(19) United States
(12) Patent Application Publication
(10) Pub. No.: US 2026/0304850 A1
(43) Pub. Date: Oct. 1, 2026

(54) POWER MOSFET DEVICE HAVING A SOURCE REGION EMBEDDED VIA HETEROEPITAXIAL GROWTH AND MANUFACTURING METHOD FOR POWER MOSFET DEVICE

(71) Applicant: CHONGQING SIMIC SEMICONDUCTOR LIMITED, CHONGQING (CN)

(72) Inventor: LI YANG, CHONGQING (CN)

(21) Appl. No.: 19/568,814

(22) Filed: Mar. 17, 2026

(30) Foreign Application Priority Data
Mar. 28, 2025 (CN) 202510386349.1

(51) Int. Cl. H10D 30/69; H10D 30/01; H10D 30/66; H10D 62/822; H10D 64/23

(52) U.S. Cl. CPC H10D 30/797; H10D 30/0295; H10D 30/0297; H10D 30/668; H10D 62/822; H10D 64/2527

(57) ABSTRACT

A manufacturing method for a power MOSFET device having a source region embedded via heteroepitaxial growth, includes: growing an epitaxial layer on a silicon substrate; forming a trench gate structure on the epitaxial layer; forming a body region on an upper part of the epitaxial layer by injection; thermally activating the impurities in the body region, where silicon disposed at an upper part of the epitaxial layer and the trench gate structure is oxidized to form a surface oxide layer; removing a portion of the surface oxide layer formed in a predetermined region; performing anisotropic etching to etch the predetermined region to form a source groove; growing heteroepitaxy to fill the source groove to form a source region; preparing a source contact penetrating the source region and extending into the body region, forming an ohmic contact area at a bottom of the source contact; and performing subsequent preparing processes.

### CROSS REFERENCE TO RELATED APPLICATIONS

The present application claims the priority of the Chinese patent application No. 202510386349.1, filed on Mar. 28, 2025, contents of which are incorporated herein by its entireties.

### TECHNICAL FIELD

Embodiments of the present disclosure relate to the technical field of power MOSFET devices, and more specifically, to a power MOSFET device having a source region embedded via heteroepitaxial growth and a manufacturing method for the power MOSFET device.

### BACKGROUND

In a MOSFET device, carriers in a conductive channel may be subject to gate oxide-silicon interface defect scattering and electric field strength perpendicular to the gate oxide-silicon interface. When the electric field strength perpendicular to a gate interface increases, a carrier density in the conductive channel may increase and may shift closer to the gate oxide-silicon interface, and therefore, the carriers may be more easily affected by the interface defect. In this way, mobility of the carriers in the conductive channel may be significantly lower than mobility of carriers in a body region. In a power MOSFET device having a low threshold voltage, a gate oxide layer may be thinner, a stronger electric field may be generated, and therefore, the mobility of the carriers in the conductive channel may be more easily affected by the stronger electric field.

### SUMMARY

In order to solve the above technical problem, the present disclosure provides a power MOSFET device having a source region embedded via heteroepitaxial growth and a manufacturing method for the power MOSFET device.

The present disclosure provides a manufacturing method for a power MOSFET device having a source region embedded via heteroepitaxial growth, including following operations.

S100, growing an epitaxial layer on a silicon substrate.

S200, forming a trench gate structure on the epitaxial layer.

S300, forming a body region on an upper part of the epitaxial layer by injecting impurities in the upper part of the epitaxial layer; activating the impurities in the body region through a thermal process. Silicon disposed at an upper part of the epitaxial layer and at an upper part of the trench gate structure is oxidized to form a surface oxide layer.

S400, removing a portion of the surface oxide layer formed in a predetermined region; and performing anisotropic etching to etch the predetermined region to form a source groove.

S500, growing heteroepitaxy to fill the source groove to form a source region.

S600, preparing a source contact penetrating the source region and extending into the body region, forming an ohmic contact area at a bottom of the source contact.

S700, performing subsequent preparing processes.

The present disclosure provides a power MOSFET device having a source region embedded via heteroepitaxial growth, formed by performing the manufacturing method in the above aspect.

According to the present disclosure, an anisotropic etching process is performed to etch a region in which a source region is to be formed, so as to form a source trench. Subsequently, the source region is formed by performing embedded heteroepitaxial growth. Desired elastic deformation is generated based on a difference between a lattice constant of a heteroepitaxial material and a lattice constant of a silicon material. A localized stress is applied to silicon disposed near the conductive channel along a source-drain direction. In this way, mobility of carriers in the source-drain direction may be improved, further reducing an on-resistance of the power MOSFET device and reducing power consumption.

### BRIEF DESCRIPTION OF THE DRAWINGS

FIG. 1 is a structural schematic view of a power MOSFET device in the related art.

FIG. 2 is a structural schematic view of another power MOSFET device in the related art.

FIG. 3 is a flow chart of a manufacturing method for a power MOSFET device having a source region embedded via heteroepitaxial growth, according to some embodiments of the present disclosure.

FIG. 4 is a structural schematic view of a structure obtained after a hard mask being formed, according to some embodiments of the present disclosure.

FIG. 5 is a structural schematic view of a structure obtained after a gate trench pattern being formed by etching, according to some embodiments of the present disclosure.

FIG. 6 is a structural schematic view of a structure obtained after a gate trench being formed by etching and after the hard mask being removed, according to some embodiments of the present disclosure.

FIG. 7 is a structural schematic view of a structure obtained after a gate oxide layer being grown, according to some embodiments of the present disclosure.

FIG. 8 is a structural schematic view of a structure obtained after a trench gate structure being formed, according to some embodiments of the present disclosure.

FIG. 9 is a structural schematic view of a structure obtained after a body region being formed by injection, according to some embodiments of the present disclosure.

FIG. 10 is a structural schematic view of a groove in the source region, being formed by etching, according to some embodiments of the present disclosure.

FIG. 11 is a structural schematic view of a structure obtained after the source region being formed via heteroepitaxial growth, according to some embodiments of the present disclosure.

FIG. 12 is a structural schematic view of a structure obtained after a silicon dioxide dielectric layer being formed, according to some embodiments of the present disclosure.

FIG. 13 is a structural schematic view of a structure obtained after a source contact hole being formed, according to some embodiments of the present disclosure.

FIG. 14 is a structural schematic view of a structure obtained after an ohmic contact area being formed, according to some embodiments of the present disclosure.

FIG. 15 is a structural schematic view of a structure obtained after a source contact being formed, according to some embodiments of the present disclosure.

### DETAILED DESCRIPTIONS

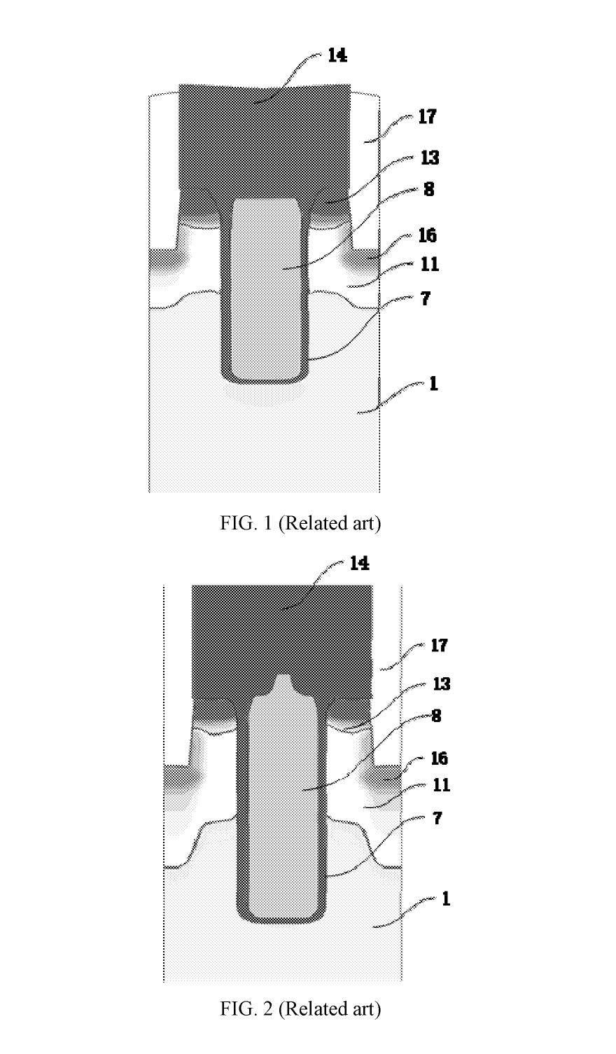

FIG. 1 shows a power MOSFET device available in the related art. A gate polysilicon 8 of the power MOSFET device in the related art is formed after back-etching, such that a height of the gate polysilicon 8 is lower than an upper surface of an epitaxial layer 1. FIG. 2 shows another power MOSFET device available in the related art. The gate polysilicon 8 is formed by chemical mechanical polishing after forming a hard mask, such that a protrusion structure that protrudes out of the upper surface of the epitaxial layer 1 is formed at a gate trench pattern 5 of the hard mask. Although the gate polysilicon 8 in the power MOSFET device in FIG. 1 and the gate polysilicon 8 in the power MOSFET device in FIG. 2 are structurally different from each other, a source region 12 in the power MOSFET device in FIG. 1 and a source region 12 in the power MOSFET device in FIG. 2 are both activated by an ion implantation process (with an implantation concentration of 10¹⁵ cm⁻³ approximately and a concentration peak formed at 10¹⁹ cm⁻³ to 10²⁰ cm⁻³) and a high-temperature thermal process (900° C. to 1000° C. for 30 to 60 minutes). Therefore, resistance may be reduced by an increased carrier concentration provided by impurity doping, and carriers in a conductive channel may be significantly affected by defects at a gate oxide-silicon interface.

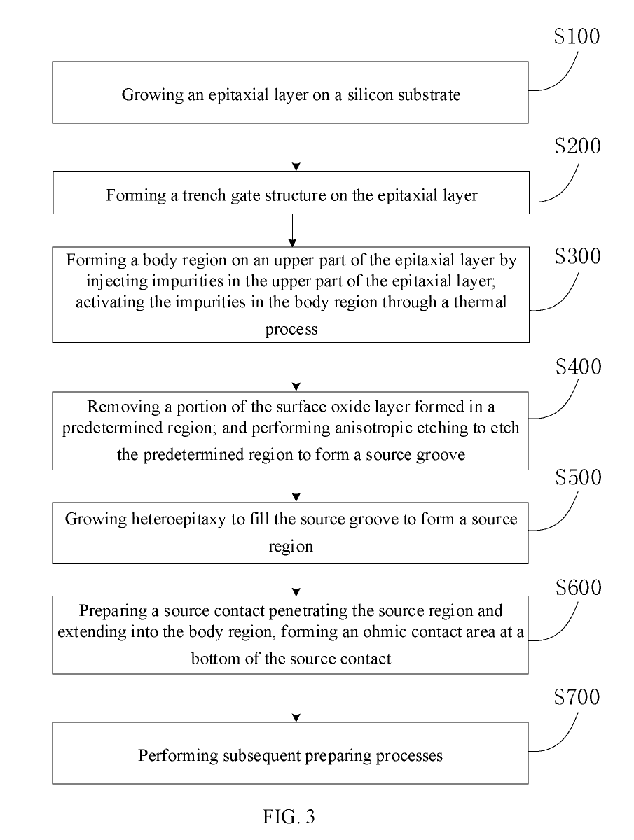

FIG. 3 is a flow chart of a manufacturing method for a power MOSFET device having a source region embedded via heteroepitaxial growth, according to some embodiments of the present disclosure. The manufacturing method of the present disclosure includes following operations.

In S100, an epitaxial layer 1 is growing on a silicon substrate. The epitaxial layer 1 may include one or more layers. The epitaxial layer 1 is typically formed via chemical vapor deposition and may be doped with trivalent elements (such as boron) or pentavalent elements (such as arsenic, phosphorus) based on polarity of the power MOSFET device. A thickness of the epitaxial layer 1 is typically determined based on an operating voltage, or the epitaxial layer 1 may be configured as a multi-layer structure based on the operating voltage.

It should be noted that the drawings show only the epitaxial layer 1, and the silicon substrate beneath the epitaxial layer 1 is omitted. Furthermore, the drawings are schematic views of relevant regions of one unit cell during the manufacturing process, and a complete structural schematic view is not shown.

In S200, a trench gate structure is prepared on the epitaxial layer 1. Preparing the trench gate structure may include following sub-operations.

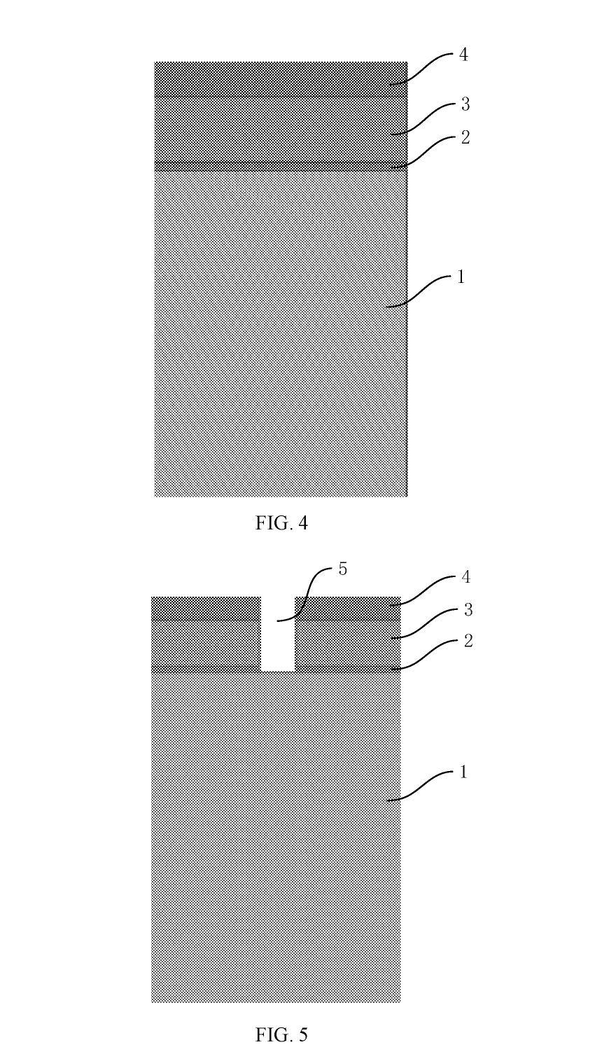

In S210, as shown in FIG. 4, a hard mask is formed on the epitaxial layer 1. The hard mask may be a silicon dioxide mask layer 4 formed on the epitaxial layer 1. In the present embodiment, the hard mask includes a silicon dioxide pad layer 2, a silicon nitride mask layer 3, and a silicon dioxide mask layer 4, which are sequentially formed on the epitaxial layer 1. In this way, an insulating mask, having a multi-layered structure of silicon dioxide--silicon nitride--silicon dioxide, is formed as the hard mask. Both the silicon dioxide mask layer 4 and the silicon nitride mask layer 3 may be prepared by performing chemical vapor deposition (CVD).

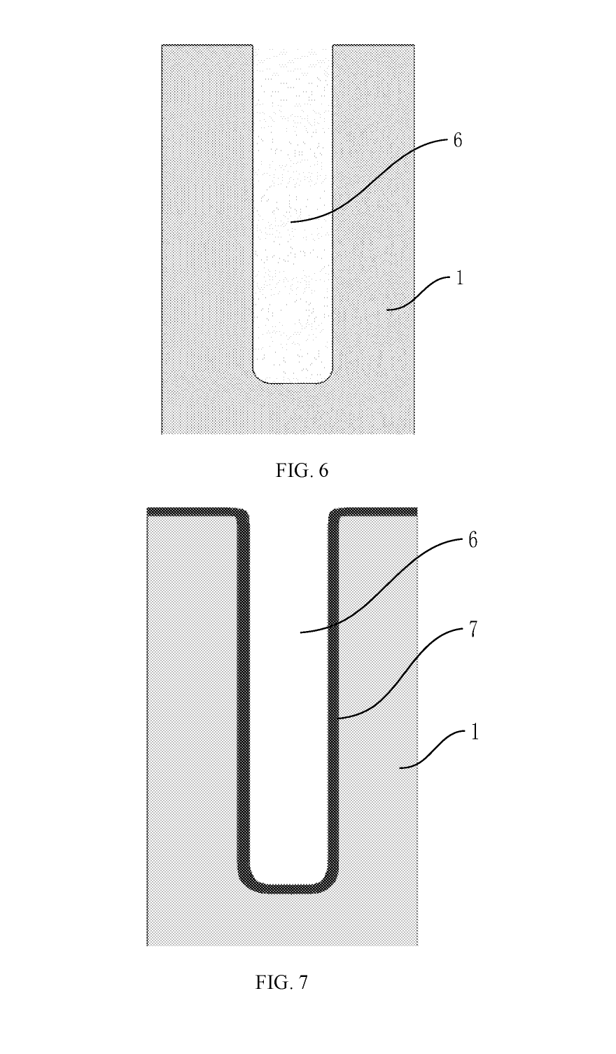

In S220, as shown in FIG. 5, a gate trench pattern 5 is formed by performing a photolithography process on the hard mask. Subsequently, as shown in FIG. 6, a gate trench 6 is formed in the epitaxial layer 1 by etching. Specifically, in the present operation, a photoresist is firstly arranged to cover the silicon dioxide mask layer 4. A pattern of the gate trench 6 pattern is exposed on the photoresist based on a mask. Subsequently, dry etching is performed based on the pattern on the photoresist to etch the silicon dioxide mask layer 4, the silicon nitride mask layer 3, and the silicon dioxide pad layer 2, so as to form the gate trench pattern 5 on the hard mask. Finally, dry etching is performed to form the gate trench 6 on epitaxial layer 1 based on the gate trench pattern 5.

In S230, as shown in FIG. 6, the photoresist and the hard mask (i.e., the silicon dioxide pad layer 2, the silicon nitride mask layer 3, and the silicon dioxide mask layer 4) are removed via wet etching, and wet cleaning is performed.

In S240, a thermal oxidation process is performed to grow a layer of silicon dioxide, serving as a sacrificial oxide layer (not shown in the drawing), on a trench wall of the gate trench 6, and the sacrificial oxide layer is removed via wet etching. A thickness of the sacrificial oxide layer is 5 nm to 50 nm. By forming the sacrificial oxide layer, the thermal oxidation process may perform rounding and plasma damage repair on cell trenches and gate interconnect trenches.

In S250, as shown in FIG. 7, a gate oxide layer 7 is grown on the trench wall of the gate trench 6 through the thermal oxidation process. A thickness of the grown gate oxide layer 7 is determined based on performance requirements of the power MOSFET device, and the thickness of the grown gate oxide layer 7 may be in a range from 5 nm to 50 nm.

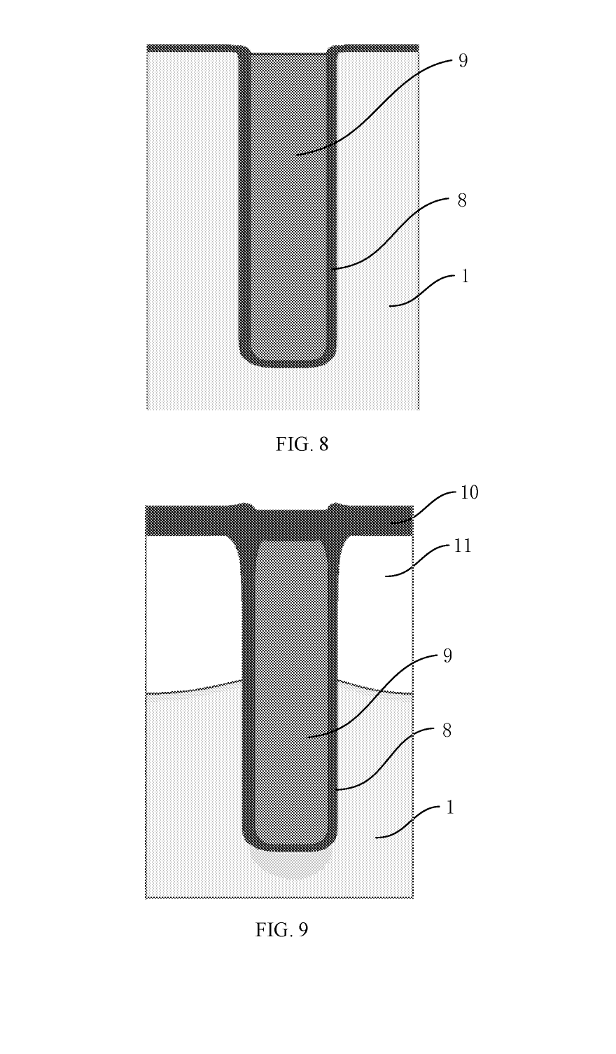

In S260, as shown in FIG. 8, a gate polysilicon 9 is deposited via low-pressure chemical vapor deposition. The gate polysilicon 8 must fully fill the gate trench 6. A thickness of the gate polysilicon 8 is determined by an actual depth of the gate trench 6.

In S270, as shown in FIG. 8, a portion of the gate polysilicon 8 disposed out of the gate trench 6 is removed by chemical mechanical polishing. When the gate oxide layer 7 is growing on the trench wall of the gate trench 6, an oxide layer may further be formed on the surface of the epitaxial layer 1 disposed out of the gate trench 6. Therefore, the oxide layer formed on the surface of the epitaxial layer 1 may serve as a stop layer during the chemical mechanical polishing. Of course, since a point at which the chemical mechanical polishing stops cannot be precisely set, during the chemical mechanical polishing, the chemical mechanical polishing is continuously performed after reaching the oxide layer formed on the surface of the epitaxial layer 1.

In S280, as shown in FIG. 8, configuration of the gate polysilicon 8 on the silicon platform is adjusted via dry etching to obtain the trench gate structure. The present operation primarily aims to remove a portion of the gate polysilicon 8 extending laterally from the gate trench 6 to the surface of the epitaxial layer 1 located at two sides of the gate trench 6 (i.e., the silicon platform). In this way, ion implantation at a later stage may not be affected, and a gate resistance is adjusted. Of course, the part of the gate polysilicon 8 extending laterally from the gate trench 6 into the silicon platform may not be fully removed, and a small amount of the part of the gate polysilicon 8 may be left on the silicon platform at a region that would not affect the ion implantation into the body region 10.

In S300, as shown in FIG. 9, the body region 10 is formed by performing the ion implantation to inject impurities into an upper portion of the epitaxial layer 1, and a thermal process is performed to activate the impurities in the body region 10. The impurities implanted to form the body region 10 may be trivalent elements or pentavalent elements, and a type of the trivalent elements or the pentavalent elements is determined based on the polarity of the power MOSFET device. During performing the thermal process to activate the impurities in the body region 10, silicon disposed on the epitaxial layer 1 and an upper portion of the gate polysilicon 8 may be oxidized to form silicon dioxide, so as to form a surface oxide layer 9.

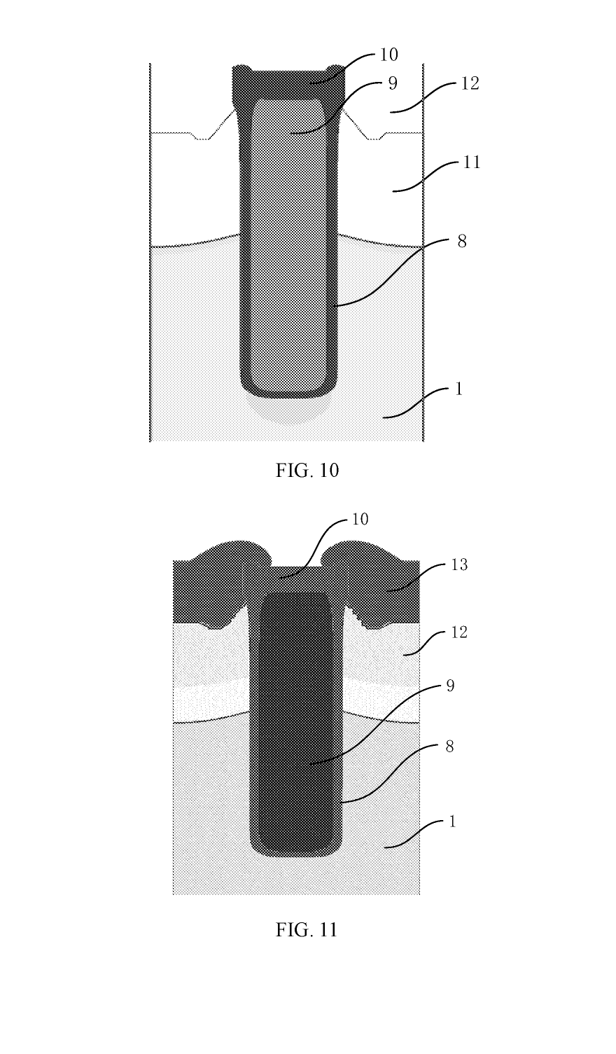

In S400, as shown in FIG. 10, the surface oxide layer 9 in a predetermined region is removed, and anisotropic etching is performed to etch the predetermined region to form a source groove 11. The predetermined region is a region for forming a source region 12. When removing the surface oxide layer 9 in the predetermined region, a source region mask may be used. A photolithography process is performed to remove the surface oxide layer 9 on a surface of the region that is used to form the source region 12, so as to expose a silicon surface of the epitaxial layer 1 located in the region.

S500, as shown in 11, epitaxial growth technology is applied to grow a heteroepitaxial layer on the exposed silicon surface, and the source groove 11 is filled by growing the heteroepitaxial layer to form the source region 12. In the present embodiment, the heteroepitaxial layer protrudes upwardly at a position near the trench gate structure and extends to an upper end of the surface oxide layer 9 disposed above the trench gate structure.

In the present operation, for a PMOS device, since the carriers in the conductive channel are holes, a compressive stress needs to be applied in a source-drain direction to improve hole mobility. At this stage, the source region 12 is formed by epitaxially growing a material having a lattice spacing greater than a lattice spacing of silicon. In the present embodiment, for the PMOS device, SiGe is epitaxially grown to form the source region 12 at a temperature of 500° C. to 800° C. Simultaneously, a pentavalent element (such as boron) is in-situ doped at a concentration in a range from E18 cm⁻³ to E19 cm⁻³. A concentration peak is formed between E19 cm⁻³ and E20 cm⁻³.

A room temperature lattice constant of silicon is 5.43 Å, and a room temperature lattice constant of germanium is 5.66 Å. Si_(1-x)Ge_x is grown in the source region 12, and Ge is doped at a certain proportion, which is typically 10% to 30%. Since the lattice spacing of SiGe is greater than that of silicon, the silicon at the conductive channel is compressed. In this way, the compressive stress is applied to the conductive channel along the source-drain direction, such that the hole mobility is improved.

For an NMOS device, electrons serve as the carriers in the conductive channel, and a tensile stress needs be applied in the source-drain direction to improve electron mobility. In this case, the source region 12 is formed by epitaxially growing a material having a lattice spacing smaller than that of silicon. In the present embodiment, for the NMOS device, SiC is epitaxially grown to form the source region 12 at a temperature of 1500° C. to 1700° C. Simultaneously, a trivalent element (such as phosphorus) is in-situ doped at a concentration in a range of E18 cm⁻³ to E19 cm⁻³, where a concentration peak is formed between E19 cm⁻³ and E20 cm⁻³. Of course, high temperatures are required to achieve conventional epitaxial growth of SiC, and therefore, in order to reduce temperatures during the epitaxial growth, SiC may alternatively be epitaxially grown by atomic layer deposition to form the source region 12 at a temperature in a range of 580° C. to 620° C.

The room temperature lattice constant of Si is 5.43 Å, and a room temperature lattice constant of C is 3.567 Å. Si_(1-x)C_x is grown in the source region 12 and C is doped at a certain proportion, which is typically 1% to 2% (due to low substitution solubility of C in silicon). Since the lattice spacing of SiC is smaller than that of silicon, the tensile stress is applied to the silicon at the conductive channel. In this way, the tensile stress is applied to the conductive channel along the source-drain direction, such that the electron mobility is improved.

In S600, a source contact penetrating the source region 12 and extending into the body region 10 is prepared, an ohmic contact area 15 is formed at a bottom of the source contact. The present operation S600 may include following sub-operations.

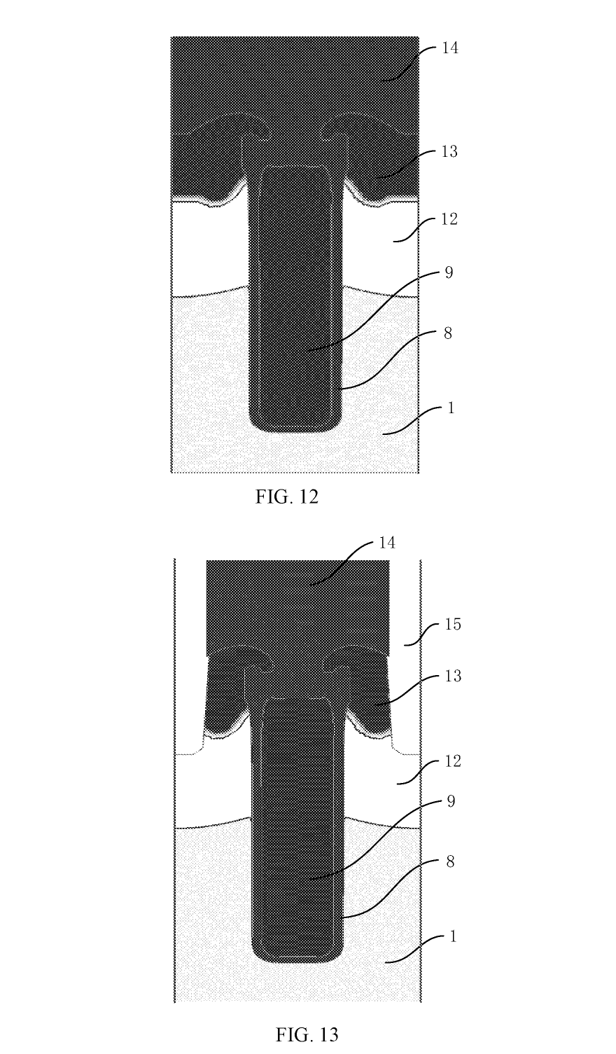

In S610, as shown in FIG. 12, a silicon dioxide dielectric layer 13 is formed on the epitaxial layer 1 via chemical vapor deposition.

In S620, as shown in FIG. 13, a pattern of the source contact hole 14 is defined using photoresist, and the silicon dioxide dielectric layer 13 and the epitaxial layer 1 are etched by dry etching to form the source contact hole 14.

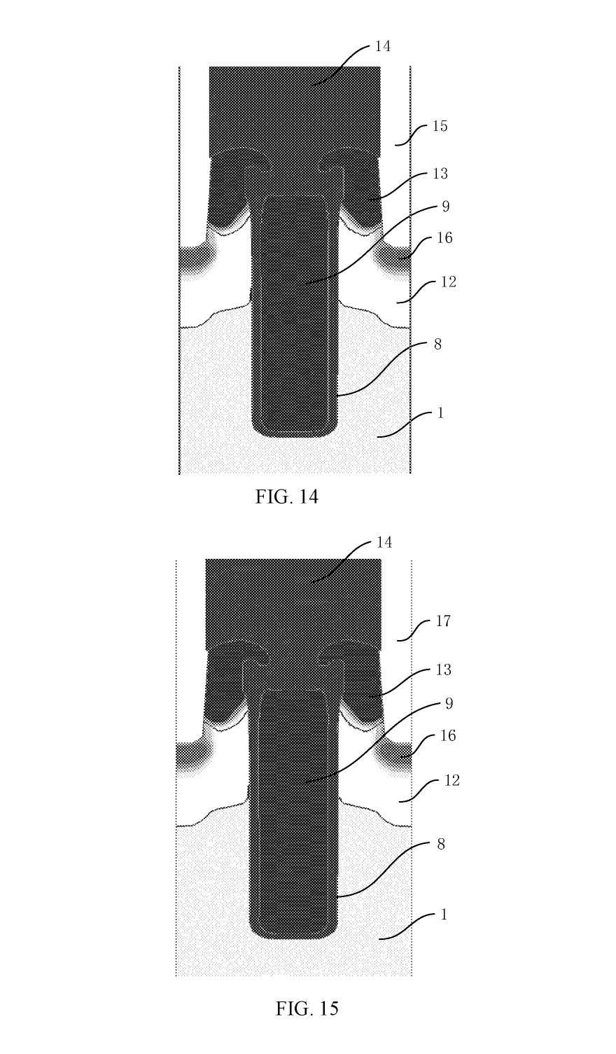

In S630, as shown in FIG. 14, ion implantation is performed to dope high concentration of impurities into the bottom of the source contact hole 14 to form the ohmic contact area 15 at the bottom of the source contact hole 14. In the present sub-operation, polarity of elements of the impurities that are ion-implanted is opposite to that of the elements of the impurities doped in the source region 12.

In S640, the impurities are activated by rapid thermal annealing.

In S650, as shown in FIG. 15, the metal tungsten is deposited in the source contact hole 14 via a tungsten plug process, a part of the tungsten disposed outside the source contact hole 14 is removed via dry etching, so as to form a tungsten plug 16 within the source contact hole 14 to serve as the source contact. Before depositing the tungsten, metals and nitrides may be deposited via physical vapor deposition to serve as a contact hole protection layer. Rapid thermal degradation is performed to form silicides; and the metals may include one or more of: titanium, cobalt, or tantalum.

In S700, subsequent preparing processes are performed. The subsequent preparing processes typically include: depositing aluminum-copper compounds over the tungsten plug 17 via physical vapor deposition; and forming circuits by performing photolithography and dry etching; depositing a passivation layer and etching the passivation layer to form openings via photolithography (the passivation layer typically includes silicon nitride or silicon dioxide); performing alloy annealing, and so on. These are conventional processes for preparing the power MOSFET device in the related art and are unrelated to improvements of the present embodiment, and therefore, these processes are not elaborated in detail here.

TCAD simulation for the power MOSFET device shown in FIG. 2 and for the MOSFET device of the present disclosure are obtained. According to the TCAD simulation, the MOSFET device of the present disclosure exhibits approximately 17% increase in current conduction compared to the MOSFET device in FIG. 2. Therefore, the carrier mobility and a current density at the conductive channel of the MOSFET device of the present disclosure are significantly enhanced with respect to that of the MOSFET device shown in FIG. 2. Therefore, optimization in the MOSFET device is achieved.

In the present embodiment, the anisotropic etching is first performed to etch the region for forming the source region 12, so as to form the source trench 11. Subsequently, the source region 12 is formed by embedded heteroepitaxial growth. Various types of heteroepitaxial materials may be embedded according to specific device types. For the NMOS device, the tensile stress is applied to reduce a conduction band height and to enhance electron mobility in the source-drain direction. For the PMOS device, the compressive stress is applied to increase a valence band height and to enhance the hole mobility in the source-drain direction. In this way, an on-resistance of power MOSFET device is further reduced, reducing power consumption.

The present invention further provides a power MOSFET device having a source region embedded via heteroepitaxial growth. The power MOSFET device may be prepared by performing any of the above methods for producing the power MOSFET device having the source region embedded via heteroepitaxial growth. In the present disclosure, the source region 12 of the power MOSFET device is formed by embedded heteroepitaxial growth. By achieving various elastic deformation caused by various lattice constants of silicon and the heteroepitaxy layer, various localized stresses are applied to the silicon disposed near the conductive channel along the source-drain direction. In this way, the carrier mobility in the conductive channel is improved, and power consumption is reduced.

What is claimed is:

1. A manufacturing method for a power MOSFET device having a source region embedded via heteroepitaxial growth, comprising:
S100, growing an epitaxial layer on a silicon substrate;
S200, forming a trench gate structure on the epitaxial layer;
S300, forming a body region on an upper part of the epitaxial layer by injecting impurities in the upper part of the epitaxial layer; activating the impurities in the body region through a thermal process, wherein, silicon disposed at an upper part of the epitaxial layer and at an upper part of the trench gate structure is oxidized to form a surface oxide layer;
S400, removing a portion of the surface oxide layer formed in a predetermined region; and performing anisotropic etching to etch the predetermined region to form a source groove;
S500, growing heteroepitaxy to fill the source groove to form a source region;
S600, preparing a source contact penetrating the source region and extending into the body region, forming an ohmic contact area at a bottom of the source contact; and
S700, performing subsequent preparing processes.

2. The manufacturing method according to claim 1, wherein, the forming the trench gate structure comprises:
S210, preparing a hard mask on the epitaxial layer;
S220, performing etching, based on photolithography and photoresist, to form a gate trench pattern on the hard mask and performing etching on the epitaxial layer to form a gate trench;
S230, removing the photoresist and the hard mask via wet etching, and performing wet cleaning;
S240, performing thermal oxidation to grow a layer of silicon dioxide, serving as a sacrificial oxide layer, on a trench wall of the gate trench; and removing the sacrificial oxide layer via wet etching;
S250, performing thermal oxidation to grow a gate oxide layer on the trench wall of the gate trench;
S260, depositing gate polysilicon via low-pressure chemical vapor deposition;
S270, removing a part of the gate polysilicon disposed out of the gate trench via chemical mechanical grinding;
S280, adjusting configuration of the gate polysilicon on a silicon platform via dry etching to obtain the trench gate structure.

3. The manufacturing method according to claim 2, wherein, in the S210, the hard mask is a silicon dioxide mask layer formed on the epitaxial layer; or the hard mask comprises mask layers of a silicon dioxide pad layer, a silicon nitride mask layer, and a silicon dioxide mask layer that are sequentially formed on the epitaxial layer.

4. The manufacturing method according to claim 1, wherein the S600 further comprises:
S610, forming a silicon dioxide dielectric layer on the epitaxial layer via chemical vapor deposition;
S620, defining a pattern of a source contact hole using photoresist and forming the source contact hole by dry etching the silicon dioxide dielectric layer and the epitaxial layer;
S630, forming the ohmic contact area at the bottom of the source contact hole via ion implantation;
S640, activating the impurities through rapid thermal annealing;
S650, depositing metal tungsten in the source contact hole via a tungsten plug process, and removing a part of the metal tungsten disposed out of the source contact hole via dry etching to form a tungsten plug, serving as the source contact, within the source contact hole.

5. The manufacturing method according to claim 1, wherein, in the S400, when removing the surface oxide layer from the predetermined region, a photolithography process is performed based on a mask to etch away the surface oxide layer disposed in the predetermined region, so as to expose a silicon surface.

6. The manufacturing method according to claim 1, wherein, in the S500, the heteroepitaxy protrudes upwardly at a position near the trench gate structure and extends to an upper end of the surface oxide layer disposed above the trench gate structure.

7. The manufacturing method according to claim 1, wherein:
when the power MOSFET device is a PMOS device, in the S500, the source region is formed by epitaxially growing a material having a lattice spacing larger than a lattice spacing of silicon; and
when the power MOSFET device is an NMOS device, in the S500, the source region is formed by epitaxially growing a material having the lattice spacing less than the lattice spacing of silicon.

8. The manufacturing method according to claim 7, wherein:
when the power MOSFET device is the PMOS device, in the S500, SiGe is epitaxially grown to form the source region at a temperature of 500°C to 800°C; and
when the power MOSFET device is the NMOS device, in the S500, SiC is grown to form the source region via epitaxial growth at a temperature of 1500°C to 1700°C; or SiC is grown to form the source region via atomic layer deposition at a temperature of 580°C to 620° C.

9. The manufacturing method according to claim 7, wherein:
when the power MOSFET device is the PMOS device, during forming the source region via heteroepitaxial growth, a pentavalent element is simultaneously in-situ doped;
when the power MOSFET device is the NMOS device, during forming the source region via heteroepitaxial growth, a trivalent element is simultaneously in-situ doped, a doping concentration is in a range of E18 cm⁻³ to E19 cm⁻³, and a concentration peak is formed between E19 cm⁻³ and E20 cm⁻³.

10. A power MOSFET device having a source region embedded via heteroepitaxial growth, formed by performing the manufacturing method according to claim 1.
